(19) United States
(12) Patent Application Publication
(10) Pub. No.: US 2021/0183995 A1
(43) Pub. Date: Jun. 17, 2021

(54) SUPERJUNCTION SILICON CARBIDE SEMICONDUCTOR DEVICE AND METHOD OF MANUFACTURING SUPERJUNCTION SILICON CARBIDE SEMICONDUCTOR DEVICE

(71) Applicants: FUJI ELECTRIC CO., LTD., Kawasaki-shi (JP); NATIONAL INSTITUTE OF ADVANCED INDUSTRIAL SCIENCE AND TECHNOLOGY, Tokyo (JP); KABUSHIKI KAISHA TOSHIBA, Tokyo (JP)

(72) Inventors: Yusuke KOBAYASHI, Nagareyama-city (JP); Manabu TAKEI, Shiojiri-city (JP); Shinya KYOGOKU, Yokohama-city (JP); Shinsuke HARADA, Tsukuba-city (JP)

(73) Assignees: FUJI ELECTRIC CO., LTD., Kawasaki-shi (JP); NATIONAL INSTITUTE OF ADVANCED INDUSTRIAL SCIENCE AND TECHNOLOGY, Tokyo (JP); KABUSHIKI KAISHA TOSHIBA, Tokyo (JP)

(21) Appl. No.: 17/186,881

(22) Filed: Feb. 26, 2021

Related U.S. Application Data
(63) Continuation of application No. PCT/JP2019/041215, filed on Oct. 18, 2019.

(30) Foreign Application Priority Data
Nov. 29, 2018 (JP) 2018-224294

(51) Int. Cl. H01L 29/06; H01L 29/16; H01L 29/66; H01L 29/78

(52) U.S. Cl. CPC H01L 29/0634; H01L 29/1608; H01L 29/7805; H01L 29/7813; H01L 29/66734

(57) ABSTRACT

A superjunction silicon carbide semiconductor device includes a silicon carbide semiconductor substrate of a first conductivity type, a first semiconductor layer of the first conductivity type, a parallel pn structure in which epitaxially grown first column regions of the first conductivity type and ion-implanted second column regions of a second conductivity type are disposed to repeatedly alternate with one another, a second semiconductor layer of the second conductivity type, first semiconductor regions of the first conductivity type, trenches, gate electrodes provided in the trenches via gate insulating films, another electrode, and a third semiconductor layer of the first conductivity type. The first column regions have an impurity concentration in a range from 1.1×10¹⁶/cm³ to 5.0×10¹⁶/cm³.

### CROSS REFERENCE TO RELATED APPLICATIONS

This is a continuation application of International Application PCT/JP2019/041215 filed on Oct. 18, 2019 which claims priority from a Japanese Patent Application No. 2018-224294 filed on Nov. 29, 2018, the contents of which are incorporated herein by reference.

### BACKGROUND OF THE INVENTION

### 1. Field of the Invention

Embodiments of the invention relate to a superjunction silicon carbide semiconductor device and a method of manufacturing a superjunction silicon carbide semiconductor device.

### 2. Description of the Related Art

In a normal n-type channel vertical MOSFET (metal oxide semiconductor field effect transistor: insulated gate field effect transistor), an n-type conductive layer (drift layer) is the semiconductor layer having the highest resistance of semiconductor layers formed in a semiconductor substrate. Electrical resistance of this n-type drift layer greatly affects ON resistance of the vertical MOSFET overall. Reduction of the ON resistance of the vertical MOSFET overall may be realized by reducing a thickness of the n-type drift layer and thereby shortening an electrical path.

Nonetheless, the vertical MOSFET has a function of sustaining breakdown voltage by a depletion layer spreading to the high-resistance n-type drift layer in an OFF state. Therefore, in an instance in which the thickness of the n-type drift layer is reduced to reduce the ON resistance, the spreading of the depletion layer during the OFF state becomes shorter, whereby the critical field strength is easily reached by a low application voltage and breakdown voltage decreases. On the other hand, to increase the breakdown voltage of the vertical MOSFET, the thickness of the n-type drift layer has to be increased, whereby the ON resistance increases. A relationship like this between the ON resistance and the breakdown voltage is called a tradeoff relationship and in general, enhancing both properties in a tradeoff relationship is generally difficult. This tradeoff relationship between ON resistance and breakdown voltage is known to similarly exist in semiconductor devices such as IGBTs (insulated gate bipolar transistors), bipolar transistors, diodes, and the like as well.

As a structure of a semiconductor device that solves problems like those described above, a superjunction (SJ) structure is known. For example, a MOSFET having a superjunction structure (hereinafter, SJ-MOSFET) is known. FIG. 16 is a cross-sectional view depicting a structure of a conventional SJ-MOSFET.

As depicted in FIG. 16, a SJ-MOSFET 200, for example, uses, as a material, a wafer in which an n⁻-type drift layer 102 is epitaxially grown on an n⁺-type semiconductor substrate 101 that contains silicon (Si) and has a high impurity concentration. P-type column regions 130 that penetrate the n⁻-type drift layer 102 from a surface of the wafer and do not reach the n⁺-type semiconductor substrate 101 are provided. While the p-type column regions 130 do not reach the n⁺-type semiconductor substrate 101 in FIG. 16, the p-type column regions 130 may reach the n⁺-type semiconductor substrate 101.

Further, in the n⁻-type drift layer 102, is a parallel structure (hereinafter, referred to as parallel pn structure 133) in which p-type regions (the p-type column regions 130) extending in a direction orthogonal to a substrate main surface and having a narrow width in a plane parallel to the substrate main surface, and n-type regions (portions of the n⁻-type drift layer 102 sandwiched between the p-type column regions 130, hereinafter, referred to as n-type column regions 131) are disposed to repeatedly alternate one another in a plane parallel to the substrate main surface. The n-type column regions 131 configuring the parallel pn structure 133 are regions corresponding to the n⁻-type drift layer 102 and in which the impurity concentration has been increased. In the parallel pn structure 133, impurity amounts that are arithmetic products of impurity concentrations contained in the p-type column regions 130 and the n-type column regions 131 and areas thereof are substantially equal and charge balanced, thereby enabling in the OFF state, creation of a pseudo non-doped layer and increased the breakdown voltage.

The conventional SJ-MOSFET 200, for example, as described in Japanese Laid-Open Patent Publication No. 2008-016518, includes in the n⁺-type semiconductor substrate 101 at a front surface thereof, a trench-type MOS gate (insulated gate formed by a metal, an oxide film, a semiconductor) structure. On the parallel pn structure 133 in an active region in which device elements are formed and through which current flows, a MOS gate structure formed by p⁻-type base regions 116, n⁺-type source regions 117, p⁺⁺-type contact regions 118, gate insulating films 119, and gate electrodes 120 is provided.

The n⁺-type source regions 117 are provided selectively in the p⁻-type base regions 116, between adjacent trenches 123. As depicted in FIG. 16, the n⁺-type source regions 117 are provided so as to be in contact with the trenches 123.

The p⁺⁺-type contact regions 118 are provided in the p⁻-type base regions 116 that are free of the n⁺-type source regions 117, at surfaces of said p⁻-type base regions 116. The n⁺-type source regions 117 and the p⁺⁺-type contact regions 118 are exposed by contact holes that penetrate through an interlayer insulating film 121 a depth direction. A source electrode 122 is provided as a front electrode so as to be embedded in the contact holes, the source electrode 122 being in contact with the p⁺⁺-type contact regions 118 and the n⁺-type source regions 117. On a back surface (surface opposite to the n⁻-type drift layer 102) of the n⁺-type semiconductor substrate 101, a drain electrode (not depicted) is provided as a back electrode.

In the conventional SJ-MOSFET 200, the p-type column regions 130 have to be connected to the source electrode 122 and therefore, are provided directly beneath (the n⁺-type semiconductor substrate 101 side of) the contact holes of the source electrode 122. While an impurity concentration of the n-type column regions 131 is about 1.0×10¹⁶/cm³ for narrow columns of a research level and for a product level, the impurity concentration is at most that (for example, refer to Jun Sakakibara, et al., “600V-class Super Junction MOSFET with High Aspect Ratio P/N Columns Structure”, ISPSD, 2008). Further, a technique of forming a SJ-MOSFET containing silicon carbide (SiC) is commonly known (for example, refer to Japanese Laid-Open Patent Publication No. 2016-192541, Japanese Laid-Open Patent Publication No. 2018-019069, Japanese Laid-Open Patent Publication No. 2012-164707, Japanese Laid-Open Patent Publication No. 2018-142682).

### SUMMARY OF THE INVENTION

According to an embodiment of the invention, a superjunction silicon carbide semiconductor device includes a silicon carbide semiconductor substrate of a first conductivity type, having at least one surface; a first semiconductor layer of the first conductivity type, provided over the at least one surface of the silicon carbide semiconductor substrate; a parallel pn structure in which a plurality of first column regions of the first conductivity type and a plurality of second column regions of a second conductivity type are disposed to repeatedly alternate with one another in a plane parallel to the at least one surface, the parallel pn structure provided in the first semiconductor layer; a second semiconductor layer of the second conductivity type, provided over the parallel pn structure; a plurality of first semiconductor regions of the first conductivity type, selectively provided in the second semiconductor layer and having an impurity concentration higher than an impurity concentration of the first semiconductor layer; a third semiconductor layer of the first conductivity type, provided between the parallel pn structure and the second semiconductor layer, the third semiconductor layer having an impurity concentration higher than the impurity concentration of the plurality of first column regions; a plurality of trenches penetrating through the plurality of first semiconductor regions and the second semiconductor layer, and reaching the third semiconductor layer; a plurality of gate electrodes, each provided in a respective one of the trenches via a respective gate insulating film; and another electrode in contact with the plurality of first semiconductor regions and the second semiconductor layer. The plurality of first column regions have an impurity concentration that is in a range from 1.1×10¹⁶/cm³ to 5.0×10¹⁶/cm³. The plurality of first and second column regions each have crystal defects, the plurality of second column regions having more crystal defects than the plurality of first column regions.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide SJ-MOSFET according to a first embodiment.

FIG. 2 is a graph depicting carrier concentration for room temperature, in a conventional silicon carbide MOSFET.

FIG. 3 is a graph depicting carrier concentration for room temperature, in the silicon carbide SJ-MOSFET according to the first embodiment.

FIG. 4 is a graph depicting carrier concentration in the conventional silicon carbide MOSFET, during high temperatures.

FIG. 5 is a graph depicting carrier concentration in the silicon carbide SJ-MOSFET according to the first embodiment, during high temperatures.

FIG. 6 is a cross-sectional view depicting a state of the silicon carbide SJ-MOSFET according to the first embodiment during manufacture.

FIG. 7 is a cross-sectional view depicting a state of the silicon carbide SJ-MOSFET according to the first embodiment during manufacture.

FIG. 8 is a cross-sectional view depicting a state of the silicon carbide SJ-MOSFET according to the first embodiment during manufacture.

FIG. 9 is a cross-sectional view of a silicon carbide SJ-MOSFET according to a second embodiment.

FIG. 10 is a graph depicting a relationship between VDS and CDS in the silicon carbide SJ-MOSFETs according to the first and the second embodiments and a conventional MOSFET.

FIG. 11 is a graph depicting fluctuation of IDS and VDS in the silicon carbide SJ-MOSFET according to the second embodiment and the conventional MOSFET.

FIG. 12 is a graph depicting ON characteristics of the silicon carbide SJ-MOSFET according to the second embodiment and the conventional MOSFET.

FIG. 13 is a graph depicting OFF characteristics of the silicon carbide SJ-MOSFET according to the second embodiment and the conventional MOSFET.

FIG. 14 is a cross-sectional view of a structure of a silicon carbide SJ-MOSFET according to a third embodiment.

FIG. 15 is a cross-sectional view depicting a structure of a silicon carbide SJ-MOSFET according to a fourth embodiment.

FIG. 16 is a cross-sectional view depicting a structure of a conventional SJ-MOSFET.

### DETAILED DESCRIPTION OF THE INVENTION

First, problems associated with the conventional techniques are discussed. The SJ-MOSFET 200 having the described structure has built therein, as a body diode between a source and drain, a body pn diode formed by the p⁻-type base regions 116 and the n⁻-type drift layer 102. The body diode of the SJ-MOSFET 200 may be used as a freewheeling diode (FWD). The body diode transitions from a state in which forward current (reflux current) passes, to a reverse bias state (i.e., reverse recovery state) of pn junctions of the body diode. Nonetheless, this body diode has a unipolar structure and therefore, minority carriers are substantially absent and reverse recovery current is small; and as compared to a MOSFET not having a SJ structure, since a majority of high injection carriers are pulled out by low voltage, a current waveform and a voltage waveform rise sharply and so-called hard recovery easily occurs. When reverse recovery operation is hard recovery, problems arise such as destruction of the SJ-MOSFET 200 due to increased surge voltage and ringing (oscillatory waveform) occurs under high-speed operation, causing noise.

Embodiments of a superjunction silicon carbide semiconductor device and a method of manufacturing a superjunction silicon carbide semiconductor device according to the present invention is described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Cases where symbols such as n's and p's that include + or − are the same indicate that concentrations are close and therefore, the concentrations are not necessarily equal. In the description of the embodiments below and the accompanying drawings, main portions that are identical will be given the same reference numerals and will not be repeatedly described.

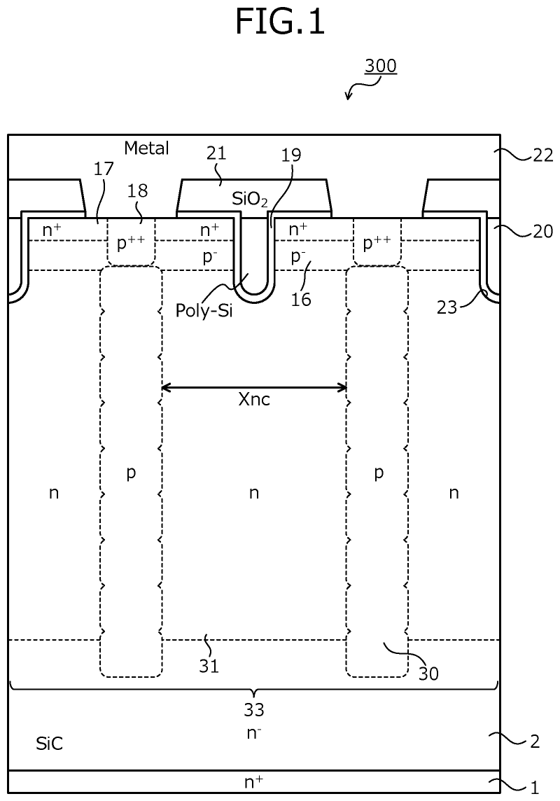

A semiconductor device according to the present invention is described taking a SJ-MOSFET as an example. FIG. 1 is a cross-sectional view depicting a structure of the silicon carbide SJ-MOSFET according to the first embodiment. A silicon carbide SJ-MOSFET 300 depicted in FIG. 1 is a SJ-MOSFET that has in a semiconductor base containing silicon carbide (SiC) (silicon carbide base: semiconductor chip), MOS (metal oxide semiconductor) gates at a front surface of the semiconductor base (surface on side having p⁻-type base regions 16). In FIG. 1, only two unit cells (functional units of a device element) are depicted and other unit cells adjacent to these are not depicted.

An n⁺-type silicon carbide substrate (silicon carbide semiconductor substrate of a first conductivity type) 1, for example, is a silicon carbide single crystal substrate doped with nitrogen (N). An n⁻-type drift layer (first semiconductor layer of the first conductivity type) 2 is a low-impurity-concentration n-type drift layer having an impurity concentration lower than an impurity concentration of the n⁺-type silicon carbide substrate 1 and doped with, for example, nitrogen. The impurity concentration of the n⁻-type drift layer 2 is, for example, in a range from 1.1×10¹⁶/cm³ to 5.0×10¹⁶/cm³. Hereinafter, the n⁺-type silicon carbide substrate 1, the n⁻-type drift layer 2, and the p⁻-type base regions 16 described hereinafter combined are regarded as a semiconductor base. In the semiconductor base, at the front surface thereof, a MOS gate (insulated gate formed by a metal, an oxide film, a semiconductor) structure (device element structure) is formed. Further, on a back surface of the semiconductor base, a drain electrode (not depicted) is provided.

In an active region of the silicon carbide SJ-MOSFET 300, parallel pn structures 33 are provided. In each of the parallel pn structures 33, n-type column regions 31 and p-type column regions 30 are disposed alternating one another. The p-type column regions 30 are provided from the surface of the n⁻-type drift layer 2 so as not to reach the surface of the n⁺-type silicon carbide substrate 1. Planar shapes of the n-type column regions 31 and the p-type column regions 30, for example, are each a stripe shape. A method of manufacturing the parallel pn structures 33 is described hereinafter. In a surface layer of each of the parallel pn structures 33, on a side thereof (first main side of the silicon carbide semiconductor base) opposite to a side thereof that faces the n⁺-type silicon carbide substrate 1, the p⁻-type base regions (second semiconductor layer of a second conductivity type) 16 are provided.

A trench structure is provided on the first main side (side having the p⁻-type base regions 16) of the silicon carbide semiconductor base. In particular, trenches 23 penetrate the p⁻-type base regions 16 from surfaces (the first main side of the silicon carbide semiconductor base) of the p⁻-type base regions 16, opposite to surfaces thereof facing the n⁺-type silicon carbide substrate 1, and the trenches 23 reach the n-type column regions 31. Along inner walls of the trenches 23, gate insulating films 19 are formed at bottoms and sidewalls of the trenches 23, and gate electrodes 20 are formed on the gate insulating films 19 in the trenches 23. The gate electrodes 20 are insulated from the n-type column regions 31 and the p⁻-type base regions 16 by the gate insulating films 19. A portion of each of the gate electrodes 20 may protrude toward a source electrode 22, from a top (side facing the source electrode 22) of the trenches 23. In the first embodiment, the trenches 23 are formed periodically in a horizontal direction in FIG. 1. The p-type column regions 30 are provided only in regions between the trenches and are not provided directly beneath the trenches.

In the p⁻-type base regions 16, n⁺-type source regions (first semiconductor regions of the first conductivity type) 17 and p⁺⁺-type contact regions 18 are selectively provided at the base first main surface. The n⁺-type source regions 17 are in contact with the trenches 23. Further, the n⁺-type source regions 17 and the p⁺⁺-type contact regions 18 are in contact with one another. Further, in the first embodiment, the p-type column regions 30 are provided directly beneath contact holes. In other words, the p-type column regions 30 are provided in regions between the n⁺-type silicon carbide substrate 1 and, the n⁺-type source regions 17 and the p⁺⁺-type contact regions 18 that are each in contact with the source electrode 22.

An interlayer insulating film 21 is provided in an entire area of the first main side of the silicon carbide semiconductor base, so as to cover the gate electrodes 20 embedded in the trenches 23. The source electrode 22 is in contact with the n⁺-type source regions 17 and the p⁺⁺-type contact regions 18, via contact holes opened in the interlayer insulating film 21. The source electrode 22 is electrically insulated from the gate electrodes 20 by the interlayer insulating film 21. On the source electrode 22, a source electrode pad (not depicted) is provided. Between the interlayer insulating film 21 and the source electrode 22, for example, a barrier metal (not depicted) that prevents diffusion of metal atoms from the source electrode 22 to the gate electrodes 20 may be provided.

Here, the electric field for dielectric breakdown is high for SiC and therefore, the impurity concentration of the n-type column regions 31 may be increased. As a result, the ON resistance may be reduced. The impurity concentration of the n-type column regions 31 may be set, for example, in a range from 1.1×10¹⁶/cm³ to 5×10¹⁶/cm³. By setting such an impurity concentration, high injection carriers during room-temperature (for example, 20 degrees C.) and high-temperature (for example, 175 degrees C.) body diode operation may be reduced as compared to a MOSFET that does not have a SJ structure. As a result, hard recovery may be suppressed by the SJ-MOSFET. Further, in the first embodiment, in an instance in which a width Xnc of the n-type column regions 31 is 3.5 μm, setting the impurity concentration of the n-type column regions 31 to be in a range from 2×10¹⁶/cm³ to 4×10¹⁶/cm³ is preferable. A depth of the p-type column regions 30 may be in a range from 3 μm to 10 μm for a breakdown voltage of 1200V, in a range from 5 μm to 15 μm for a breakdown voltage of 1700V, and in a range from 10 μm to 30 μm for a breakdown voltage of 3300V. The depth of the p-type column regions 30 suffices to be in a range from ⅓ to 1 times the thickness of the n⁻-type drift layer.

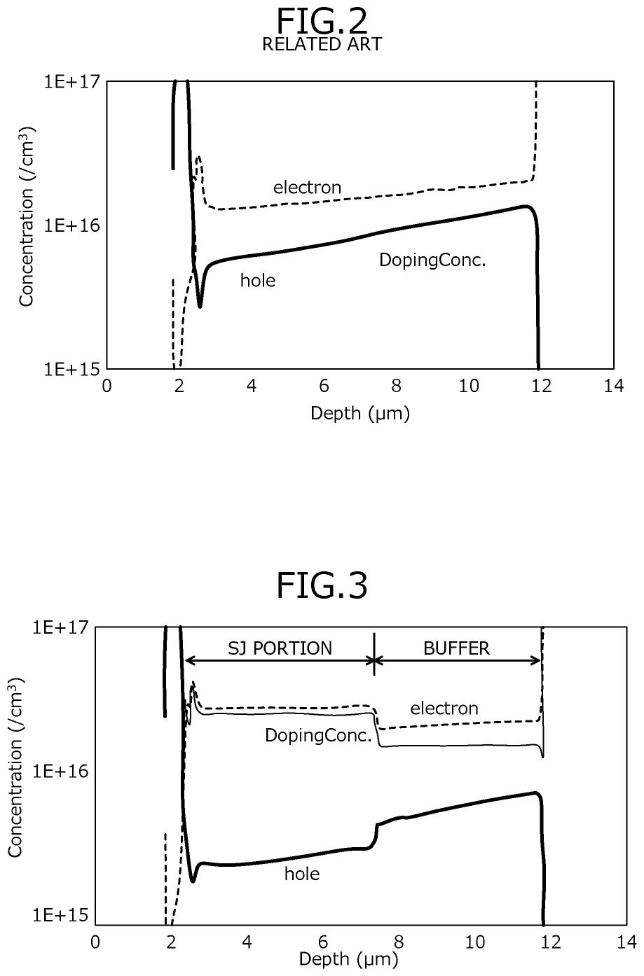

FIG. 2 is a graph depicting carrier concentration for room temperature, in a conventional silicon carbide MOSFET. Further, FIG. 3 is a graph depicting carrier concentration for room temperature, in the silicon carbide SJ-MOSFET according to the first embodiment. FIG. 2 is an example of a silicon carbide MOSFET without a SJ structure; FIGS. 2 and 3 depict impurity concentration and carrier distribution of the body diode. In FIGS. 2 and 3, a horizontal axis is depth from the semiconductor base surface in units of μm. A vertical axis indicates concentration in units of/cm³. In FIGS. 2 and 3, broken lines indicate electron concentration, thick solid lines indicate hole concentration, and thick solid lines indicate carrier (electron and hole) concentration.

Further, FIG. 2 depicts results when current having a current density of 300 A/cm² passes through the body diode of the conventional silicon carbide MOSFET. In the conventional silicon carbide MOSFET depicted in FIG. 2, the impurity concentration of the n-type drift layer is assumed to be 8×10¹⁵/cm³. FIG. 3 depicts results when current having a current density of 330 A/cm² passes through the body diode of the silicon carbide SJ-MOSFET according to the first embodiment. In the silicon carbide SJ-MOSFET according to the first embodiment depicted in FIG. 3, the impurity concentration of the n⁻-type drift layer 2 is assumed to be 1.8×10¹⁶/cm³ and the impurity concentration of the n-type column regions 31 is assumed to be 3×10¹⁶/cm³. The impurity concentration of the n-type column regions 31 is increased and the p-type column regions 30 are formed by ion implantation, whereby the lifetime is shorted by damage caused by the ion implantation. It is desirable for minority carrier lifetime in a p-layer to be in a range from 0.5 ns to 500 ns. This is because, when the minority carrier lifetime is too short, leak current during voltage blocking increases, and when the minority carrier lifetime is too long, reverse recovery characteristics degrade. The p-type column regions 30 have more crystal defects than does the n-type column regions 31 due to the ion implantation. Further, in the SJ-MOSFET, due to the p-type column regions 30, a depletion layer spreads in the horizontal direction of the p-type column regions 30 during the OFF state. Therefore, even when the impurity concentration of the n-type column regions 31 that are current paths is increased, depletion occurs easily and therefore, the ON resistance may be greatly reduced while maintaining high breakdown voltage in the OFF state.

In this manner, in the silicon carbide SJ-MOSFET according to the first embodiment, the p-type column regions 30 are formed by ion implantation, the impurity concentration of the n-type column regions 31 and that of the n⁻-type drift layer 2 are higher than the impurity concentration of the n-type drift layer of the conventional silicon carbide MOSFET and therefore, there are fewer high injection carriers when the body diode turns ON. As a result, hard recovery due to hole carriers being pulled out during the reverse recovery state may be suppressed. This suppression has an effect in an instance in which the impurity concentration of the n-type column regions 31 is higher than the impurity concentration of the n⁻-type drift layer of the conventional silicon carbide MOSFET. Nonetheless, when the impurity concentration of the n-type column regions 31 is at least equal to electron carrier concentration, the effect decreases and therefore, it is preferable for the impurity concentration of the n-type column regions 31 to be in a range from 8.1×10¹⁵/cm³ to 3.0×10¹⁶/cm³.

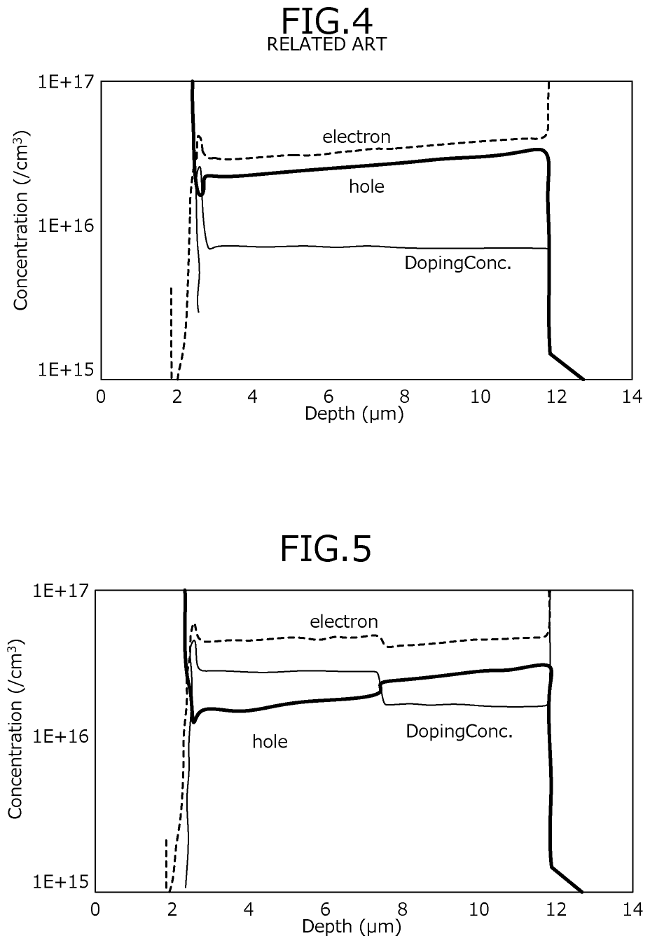

FIG. 4 is a graph depicting carrier concentration in the conventional silicon carbide MOSFET, during high temperatures. FIG. 5 is a graph depicting carrier concentration in the silicon carbide SJ-MOSFET according to the first embodiment, during high temperatures. FIGS. 4 and 5 are graphs for instances similar to those for FIGS. 2 and 3 and differ therefrom in that FIGS. 4 and 5 depict results for high temperatures. Similarly to the instances of normal temperature, the suppression of hard recovery has an effect in an instance in which the impurity concentration of the n-type column regions 31 is higher than the impurity concentration of the n-type drift layer of the conventional silicon carbide MOSFET. Nonetheless, during high-temperature operation, there are many high injection carriers and therefore, it is preferable for the impurity concentration of the n-type column regions 31 to be in a range from 1.2×10¹⁵/cm³ to 5.0×10¹⁶/cm³.

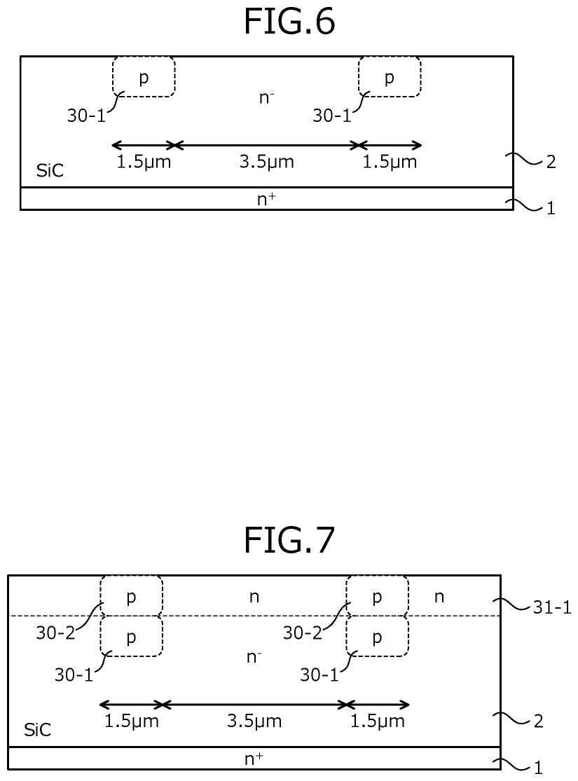

Next, a method of manufacturing the silicon carbide semiconductor device according to the first embodiment is described. FIGS. 6, 7 and 8 are cross-sectional views depicting states of the silicon carbide SJ-MOSFET according to the first embodiment during manufacture. In the first embodiment, the method of manufacture is described taking, as an example, a silicon carbide SJ-MOSFET having a trench structure of a breakdown voltage of 1.2 kV.

First, the n⁺-type silicon carbide substrate 1 containing an n-type silicon carbide is prepared. Subsequently, on a first main surface of the n⁺-type silicon carbide substrate 1, while an n-type impurity, for example, nitrogen atoms, is doped, the n⁻-type drift layer 2 containing silicon carbide is epitaxially grown to have an impurity concentration of about 1.8×10¹⁶/cm³ and a thickness in a range from about 8 μm to 12 μm.

Next, on the surface of the n⁻-type drift layer 2, an ion implantation mask having predetermined openings is formed by a photolithographic technique, using, for example, an oxide film having a film thickness of 2.0 μm. Subsequently, a p-type impurity such as aluminum is implanted through the openings of the oxide film, thereby forming first p-type column regions 30-1 of a depth in a range from 0.4 μm to 3.0 μm; it is preferable for the depth to be in a range from 0.4 μm to 2.0 μm. The first p-type column regions 30-1, for example, are formed at intervals of 3.5 μm and have widths of 1.5 μm. In the ion implantation, for example, the acceleration energy is assumed to be in a range from 60 keV to 700 keV and formation is such that an average concentration of Al in the first p-type column regions 30-1 becomes 9.0×10¹⁶/cm³. Next, the ion implantation mask is removed. The state up to here is depicted in FIG. 6.

Next, on the front side of the n⁻-type drift layer 2, for example, while nitrogen atoms are doped, first n-type column regions 31-1 containing silicon carbide and having an impurity concentration higher than the impurity concentration of the n⁻-type drift layer 2 are epitaxially grown in a range from 0.4 μm to 3.0 μm, preferably from 0.4 μm to 2.0 μm, so that the impurity concentration becomes about 3.0×10¹⁶/cm³.

Next, on the surfaces of the first n-type column regions 31-1, an ion implantation mask having predetermined openings is formed by photolithography, using, for example, an oxide film having a film thickness of 2.0 μm. Further, a p-type impurity such as aluminum is implanted through the openings of the oxide film, thereby forming second p-type column regions 30-2 of a depth in a range from 0.4 μm to 0.6 μm. The second p-type column regions 30-2, for example, are formed at intervals of 3.5 μm and have widths of 1.5 μm. In the ion implantation, for example, the acceleration energy is assumed to be in a range from 60 keV to 700 keV and formation is such that an average concentration of Al in the second p-type column regions 30-2 becomes 9.0×10¹⁶/cm³. Next, the ion implantation mask is removed. The state up to here is depicted in FIG. 7.

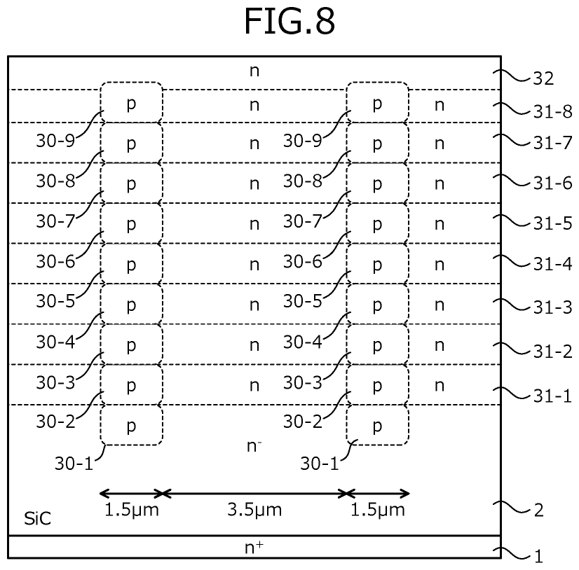

Next, the processes of ion implantation and epitaxial growth of FIGS. 6 and 7, for example, are repeated 8 times, until eighth n-type column regions 31-8 and ninth p-type column regions 30-9 are formed. Next, on the surfaces of the eighth n-type column regions 31-8, for example, while nitrogen atoms are doped, an n-type epitaxial layer 32 containing silicon carbide and having an impurity concentration higher than the impurity concentration of the n⁻-type drift layer 2 is epitaxially grown to have a film thickness of 0.5 μm and an impurity concentration of about 8.0×10¹⁶/cm³. The n-type epitaxial layer 32 may be omitted. The state up to here is depicted in FIG. 8. The first p-type column regions 30-1 to the ninth p-type column regions 30-9 combined form the p-type column regions 30, while the first n-type column regions 31-1 to the eighth n-type column regions 31-8 combined form the n-type column regions 31. Here, while the processes of the ion implantation to the epitaxial growth are repeatedly performed 8 times, this number is dependent on the film thicknesses of the parallel pn structures 33, the acceleration energy of the ion implantations, etc. and therefore, may be another number. In this manner, the processes of epitaxial growth and ion implantation are repeated for the p-type column regions 30 and therefore, in each of the first p-type column regions 30-1 to the ninth p-type column regions 30-9, even when the average concentration of Al has a box profile of 9.0×10¹⁶/cm³, regarding concentration distribution in the depth direction, each has a cross-section exhibiting one peak and two bottoms. The first p-type column regions 30-1 to the ninth p-type column regions 30-9 each having a cross-section exhibiting one peak and two bottoms form a connected periodic distribution. The first p-type column regions 30-1 to the ninth p-type column regions 30-9 are formed by ion implantation and therefore, crystal defects occur. These crystal defects recover by annealing in an instance of a silicon substrate, however, in an instance of silicon carbide, crystal defects remain even when annealing is performed. As described above, a cross-section of a vertical structure of the p-type column regions 30 having a periodic distribution of an acceptor impurity (AI) and crystal defects are structural signs due to the repeated epitaxial growth and ion implantation. The first n-type column regions 31-1 to the eighth n-type column regions 31-8 are epitaxially grown layers as they are and therefore, periodic concentration distribution and crystal defects for each layer are observed in the depth direction of the cross-sections.

Next, on the surfaces of the n-type column regions 31 and the p-type column regions 30, the p⁻-type base regions 16 doped with a p-type impurity such as aluminum are formed. Next, on the surfaces of the p⁻-type base regions 16, an ion implantation mask having predetermined openings is formed by photolithography using, for example, an oxide film. An n-type impurity such as phosphorus (P) is ion-implanted through the openings, thereby forming the n⁺-type source regions 17 in portions of the p⁻-type base regions 16, at the surfaces thereof. Next, the ion implantation mask used in forming the n⁺-type source regions 17 is removed and by a similar method, an ion implantation mask having predetermined openings is formed, a p-type impurity such as aluminum is ion-implanted in portions of the p⁻-type base regions 16, at the surfaces thereof, whereby the p⁺⁺-type contact regions 18 are provided. An impurity concentration of the p⁺⁺-type contact regions 18 is set to be higher than an impurity concentration of the p⁻-type base regions 16.

Next, a heat treatment (annealing) under an inert gas atmosphere is performed, thereby implementing an activation process of the first p-type column regions 30-1 to the ninth p-type column regions 30-9, the first n-type column regions 31-1 to the eighth n-type column regions 31-8, the n-type epitaxial layer 32, the n⁺-type source regions 17, and the p⁺⁺-type contact regions 18. As described above, ion implanted regions may be collectively activated by a single session of the heat treatment or the heat treatment may be performed each time the ion implantation is performed. Even when heat treatment (annealing) used by processes for silicon carbide is performed, impurities contained in the silicon carbide are not easily diffused. Therefore, the periodic concentration distribution of the first p-type column regions 30-1 to the ninth p-type column regions 30-9 formed by ion implantation and described above is maintained even after the heat treatment.

Next, on the surfaces of the p⁻-type base regions 16, a trench formation mask having predetermined openings is formed by photolithography using, for example, an oxide film. Next, the trenches 23 that penetrate the p⁻-type base regions 16 and reach the n-type column regions 31 are formed by dry etching. Next, the trench formation mask is removed.

Next, the gate insulating films 19 are formed along the surfaces of the n⁺-type source regions 17 and the p⁺⁺-type contact regions 18 and along bottoms and sidewalls of the trenches 23. The gate insulating films 19 may be formed by thermal oxidation by a heat treatment at a temperature of about 1000 degrees C. under an oxygen atmosphere. Further, the gate insulating films 19 may be formed by a deposition method by a chemical reaction such as that for a high temperature oxide (HTO) or the like.

Next, on the gate insulating films 19, a polycrystalline silicon layer doped with, for example, phosphorus atoms is provided. The polycrystalline silicon layer may be formed so as to be embedded in the trenches 23. The polycrystalline silicon layer is patterned by photolithography to be left in the trenches 23, thereby forming the gate electrodes 20. A portion of the gate electrodes 20 may protrude outward from the trenches 23.

Next, for example, a phosphate glass having a thickness of about 1 μm is deposited so as to cover the gate insulating films 19 and the gate electrodes 20, thereby forming the interlayer insulating film 21. Next, a barrier metal (not depicted) containing titanium (Ti) or titanium nitride (TiN) may be formed so as to cover the interlayer insulating film 21. The interlayer insulating film 21 and the gate insulating films 19 are patterned by photolithography, thereby forming the contact holes that expose the n⁺-type source regions 17 and the p⁺⁺-type contact regions 18. Thereafter, a heat treatment (reflow) is performed, thereby planarizing the interlayer insulating film 21.

Next, in the contact holes and on the interlayer insulating film 21, a conductive film such as a film of nickel (Ni) constituting the source electrode 22 is provided. The conductive film is patterned by photolithography to be left in only the contact holes as the source electrode 22.

Next, on a second main surface of the n⁺-type silicon carbide substrate 1, a back electrode (not depicted) containing nickel, etc. is provided. Thereafter, a heat treatment under an inert gas atmosphere of about 1000 degrees C. is performed, thereby forming the source electrode 22 and back electrode in ohmic contact with the n⁺-type source regions 17, the p⁺⁺-type contact regions 18, and the n⁺-type silicon carbide substrate 1.

Next, on the first main surface of the n⁺-type silicon carbide substrate 1, an aluminum film having a thickness of about 5 μm is deposited by a sputtering method, the aluminum film is removed by photolithography so that the source electrode 22 and the interlayer insulating film 21 are covered, whereby the source electrode pad (not depicted) is formed.

Next, on the surface of the back electrode, for example, titanium (Ti), nickel, and gold (Au) are sequentially stacked, whereby a drain electrode pad (not depicted) is formed. In this manner, the silicon carbide semiconductor device depicted in FIG. 1 is completed.

As described above, according to the first embodiment, by formation using SiC, the impurity concentration of the n-type column regions may be increased to be in a range from 1.1×10¹⁶/cm³ to 5×10¹⁶/cm³. Furthermore, the p-type column regions are formed by ion implantation, thereby enabling reduction of the minority carrier lifetime in p-type column regions. As a result, the high injection carriers when the body diode turns ON may be reduced. Therefore, hard recovery due to hole carriers being pulled out during the reverse recovery state may be suppressed. Furthermore, the impurity concentration of the n-type column regions is high and therefore, the ON resistance decreases.

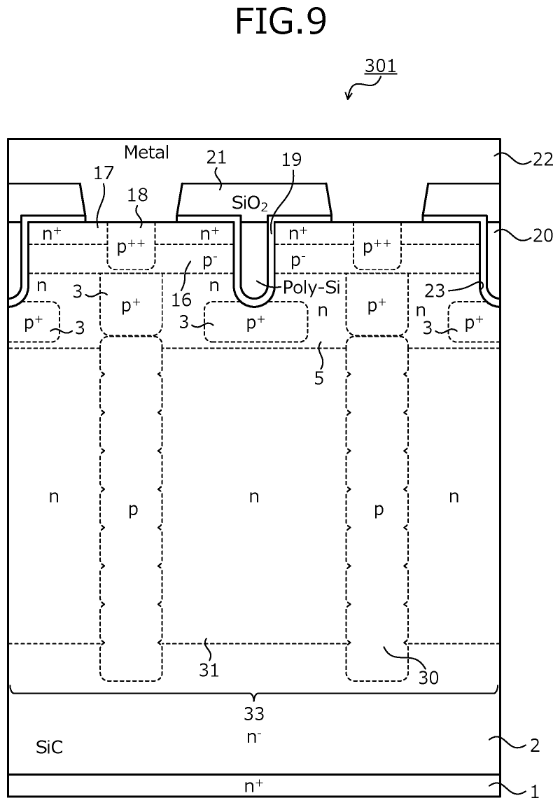

Next, a structure of a semiconductor device according to a second embodiment is described. FIG. 9 is a cross-sectional view of a silicon carbide SJ-MOSFET according to the second embodiment. As depicted in FIG. 9, a silicon carbide SJ-MOSFET 301 according to the second embodiment differs from the silicon carbide SJ-MOSFET 300 according to the first embodiment in that on surfaces of the parallel pn structures 33, n-type high-concentration regions (third semiconductor layer of the first conductivity type) 5 are provided and in the n-type high-concentration regions 5, p⁺-type regions (second semiconductor regions of the second conductivity type) 3 are selectively provided.

The n-type high-concentration regions 5 have an impurity concentration lower than the impurity concentration of the n⁺-type silicon carbide substrate 1 and higher than the impurity concentration of the n⁻-type drift layer 2 and, for example, are a high-concentration n-type drift layer doped with nitrogen. The n-type high-concentration regions 5 are a so-called current spreading layer (CSL) that reduces carrier spreading resistance. The n-type high-concentration regions 5, for example, are provided uniformly in a direction parallel to a base front surface (front surface of the semiconductor base).

Some of the p⁺-type regions 3 are provided at the bottoms of the trenches 23 and the p⁺-type regions 3 have a width greater than a width of the trenches 23. The p⁺-type regions 3, for example, are doped with aluminum (Al). Further, some of the p⁺-type regions 3 (third semiconductor regions of the second conductivity type) are provided between the trenches 23; surfaces thereof are in contact with the p⁻-type base regions 16; and bottoms surfaces thereof are in contact with the p-type column regions 30.

Provision of the p⁺-type regions 3 enables formation of pn junctions between the p⁺-type regions 3 and the n-type high-concentration regions 5, near the bottoms of the trenches 23. The pn junctions between the p⁺-type regions 3 and the n-type high-concentration regions 5 are positioned deeper than the trenches 23 and therefore, electric field concentrates at borders between the p⁺-type regions 3 and the n-type high-concentration regions 5, thereby mitigating electric field concentration at the bottoms of the trenches 23 and enabling mitigation of electric field at the gate insulating films 19.

In the silicon carbide SJ-MOSFET, in an instance in which the impurity concentration of the n-type column regions is increased and high injection carriers during body diode operation are decreased, the reverse recovery current is greatly affected by capacitance between the drain and source (CDS). Therefore, by increasing the CDS, soft recovery is further enabled.

In the silicon carbide SJ-MOSFET 301 according to the second embodiment, the n-type high-concentration regions 5 on the parallel pn structures 33 are set to have an impurity concentration at least equal to that of the n-type column regions 31, whereby the CDS is increased, thereby enabling suppression of hard recovery to a greater extent than in the first embodiment. Further, breakdown voltage defects and oxide film destruction by electric field due to increased electric field at the bottoms of the trenches 23 occur and therefore, the p⁺-type regions 3 are formed at the bottoms of the trenches 23, whereby increases in electric field are suppressed and the CDS may be increased.

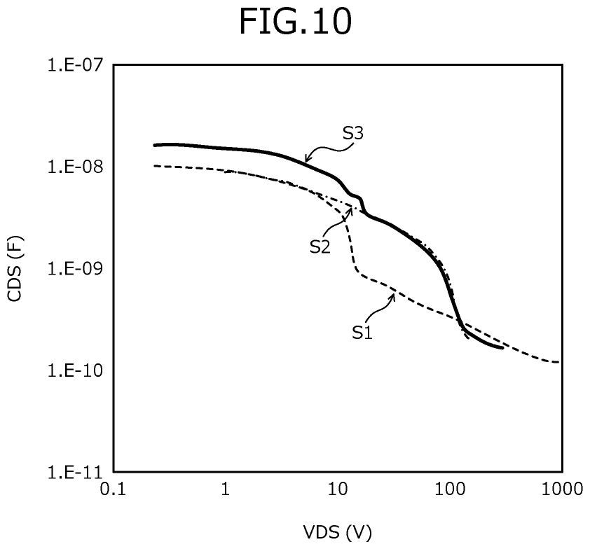

Here, FIG. 10 is a graph depicting a relationship between VDS and CDS in the silicon carbide SJ-MOSFETs according to the first and the second embodiments and a conventional MOSFET. In FIG. 10, a horizontal axis indicates VDS (drain-source voltage) in units of V; and a vertical axis indicates CDS (drain-source capacitance) in units of F. In FIG. 10, dashed line S1 is an example of a silicon carbide MOSFET that does not have a SJ structure; dash-dotted line S2 in FIG. 10 is an example of the silicon carbide SJ-MOSFET according to the first embodiment; and solid line S3 in FIG. 10 is an example of the silicon carbide SJ-MOSFET according to the second embodiment.

As depicted in FIG. 10, the silicon carbide SJ-MOSFET according to the first embodiment has a higher CDS, as compared to the silicon carbide MOSFET without a SJ structure. Furthermore, the silicon carbide SJ-MOSFET according to the second embodiment has a higher CDS as compared to the silicon carbide SJ-MOSFET according to the first embodiment.

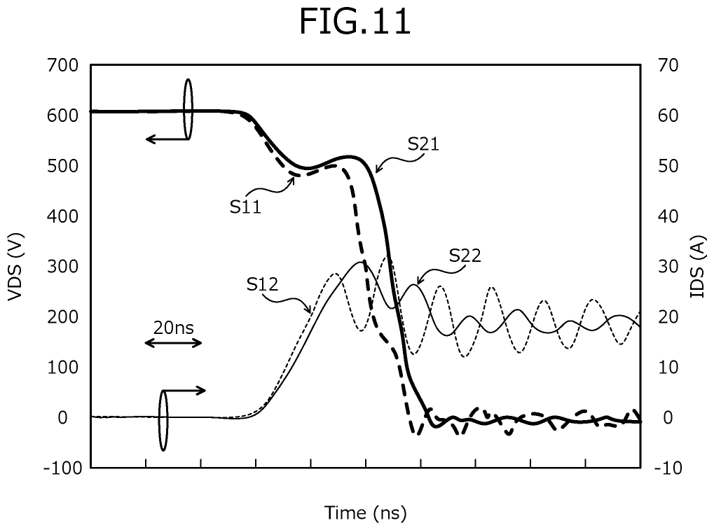

Further, FIG. 11 is a graph depicting fluctuation of IDS and VDS in the silicon carbide SJ-MOSFET according to the second embodiment and the conventional MOSFET. In FIG. 11, a horizontal axis indicates time in units of ns; a left vertical axis indicates VDS in units of V; and a right vertical axis indicates IDS (drain-source current) in units of A. In FIG. 11, dashed lines S11, S12 are examples of the silicon carbide MOSFET without a SJ structure; in FIG. 11, solid lines S21, S22 are examples of the silicon carbide SJ-MOSFET according to the second embodiment. Further, dashed line S11 and solid line S21 indicate fluctuation of VDS; and dashed line S12 and solid line S22 indicate fluctuation of IDS.

As depicted in FIG. 11, for the silicon carbide SJ-MOSFET according to the second embodiment, as compared to the conventional MOSFET, both the current waveform and the voltage waveform are soft waveforms that gently rise, and oscillation is also small. Therefore, the problems of destruction of the SJ-MOSFET due to increases in surge voltage and the occurrence of ringing (oscillatory waveform) during high speed operation, which causes noise are solved.

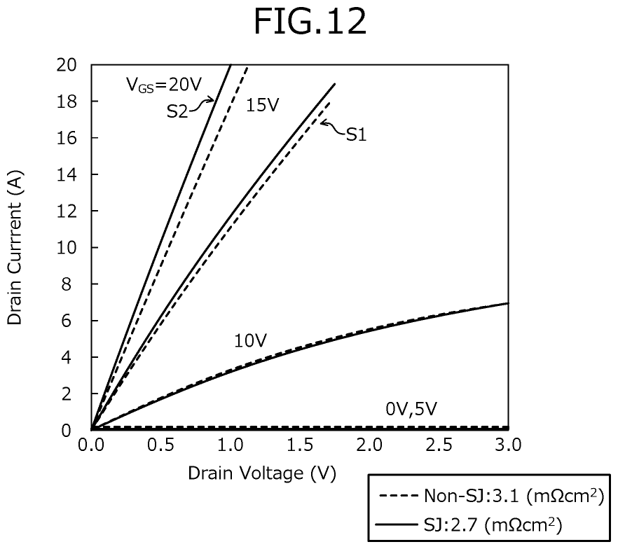

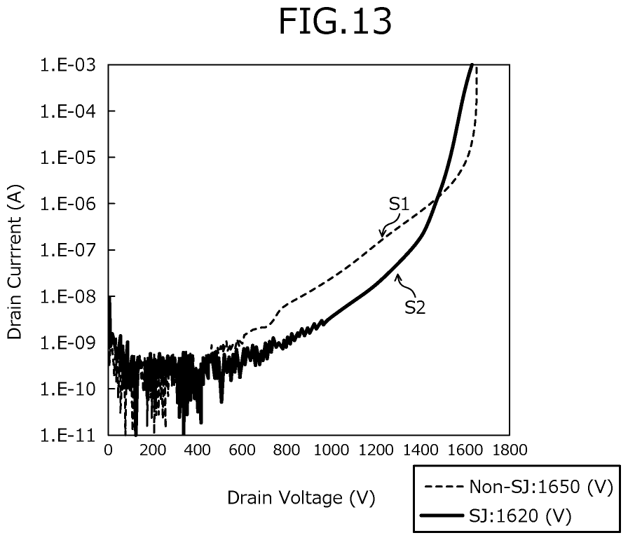

Further, FIG. 12 is a graph depicting ON characteristics of the silicon carbide SJ-MOSFET according to the second embodiment and the conventional MOSFET. FIG. 13 is a graph depicting OFF characteristics of the silicon carbide SJ-MOSFET according to the second embodiment and the conventional MOSFET. In FIGS. 12 and 13, a horizontal axis indicates drain voltage in units of V and a vertical axis indicates drain current in units of A. In FIGS. 12 and 13, dashed line S1 is an example of the silicon carbide MOSFET without a SJ structure; and in FIGS. 12 and 13, solid line S2 is an example of the silicon carbide SJ-MOSFET according to the second embodiment.

As depicted in FIG. 13, the silicon carbide SJ-MOSFET according to the second embodiment and the conventional MOSFET have equal voltages. As depicted in FIG. 12, the silicon carbide SJ-MOSFET according to the second embodiment, as compared to the conventional MOSFET, has lower ON resistance for the same breakdown voltage. Further, this trend becomes more striking the higher is the VGS (gate-source voltage).

Next, a method of manufacturing the silicon carbide semiconductor device according to the second embodiment is described. First, similarly to the first embodiment, the n⁺-type silicon carbide substrate 1 containing an n-type silicon carbide is prepared, and the processes up through forming the eighth n-type column regions 31-8 and the ninth p-type column regions 30-9 are performed (refer to FIG. 8).

Next, on the eighth n-type column regions 31-8 and the ninth p-type column regions 30-9, the n-type high-concentration regions 5 containing silicon carbide are epitaxially grown while an n-type impurity, for example, nitrogen atoms (N), is doped.

Next, on the surfaces of the n-type high-concentration regions 5, a non-depicted mask having predetermined openings is formed by a photolithographic technique using, for example, an oxide film. Subsequently, ion implantation is performed using this oxide film as a mask, whereby a p-type impurity, for example, aluminum atoms (Al), is ion-implanted. As a result, the p⁺-type regions 3 are formed in the n-type high-concentration regions 5. Next, the ion implantation mask for forming the p⁺-type regions 3 is removed.

Thereafter, similarly to the first embodiment, the process of forming the p⁻-type base regions 16 and subsequent processes are performed, whereby the silicon carbide semiconductor device depicted in FIG. 9 is completed. Further, the n-type high-concentration regions 5 and the p⁺-type regions 3 may be formed by repeatedly performing epitaxial growth and ion implantation.

As described above, according to the second embodiment, the n-type high-concentration regions are set to have an impurity concentration at least equal to the impurity concentration of the n-type column regions, whereby the CDS is increased and hard recovery may be suppressed to a greater extent than in the first embodiment. The p⁺-type regions are formed at the bottoms of the trenches, thereby enabling increases of the electric field to be suppressed and the CDS to be increased.

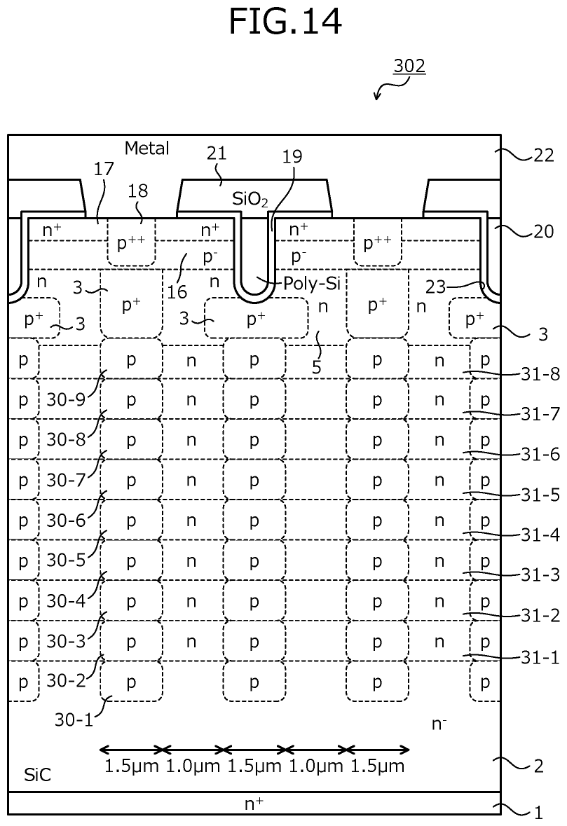

Next, a structure of a semiconductor device according to a third embodiment is described. FIG. 14 is a cross-sectional view of the structure of the silicon carbide SJ-MOSFET according to the third embodiment. As depicted in FIG. 14, a silicon carbide SJ-MOSFET 302 according to the third embodiment differs from the silicon carbide SJ-MOSFET 301 according to the second embodiment in that the p-type column regions 30 are provided directly beneath the trenches 23 (regions between the n⁻-type drift layer 2 and the p⁺-type regions 3 at the bottoms of the trenches 23).

In the third embodiment, a pitch (width between the p-type column regions 30) of the parallel pn structures 33 is a half of that in the first and the second embodiments. For example, the width of the p-type column regions 30 may be 1.5 μm and the width of the n-type column regions 31 may be 1.0 μm. Therefore, the impurity concentration of the n-type column regions 31 may be set higher than that in the first and the second embodiments, the injection carriers may be suppressed to a greater extent that in the first and the second embodiment, and the CDS may be enhanced.

Further, a method of manufacturing the silicon carbide SJ-MOSFET 302 according to the third embodiment may be implemented by changing the openings of the mask by a photolithographic technique when the first p-type column regions 30-1 to the ninth p-type column regions 30-9 are formed, in the method of manufacturing the silicon carbide SJ-MOSFET 301 according to the second embodiment.

As described above, according to the third embodiment, the p-type column regions are provided directly beneath the trenches. Therefore, the impurity concentration of the n-type column regions may be set to be higher than that in the first and the second embodiments, the injection carriers may be suppressed to a greater extent that in the first and the second embodiment, and the CDS may be enhanced.

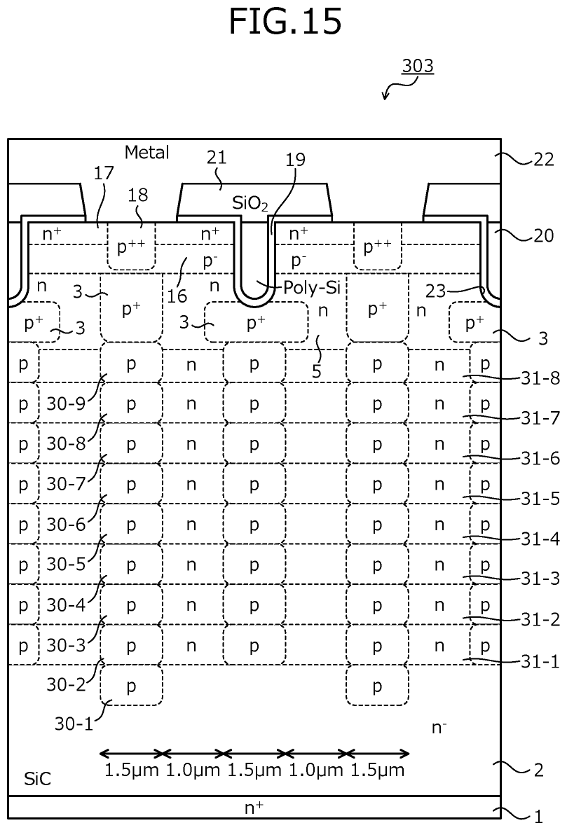

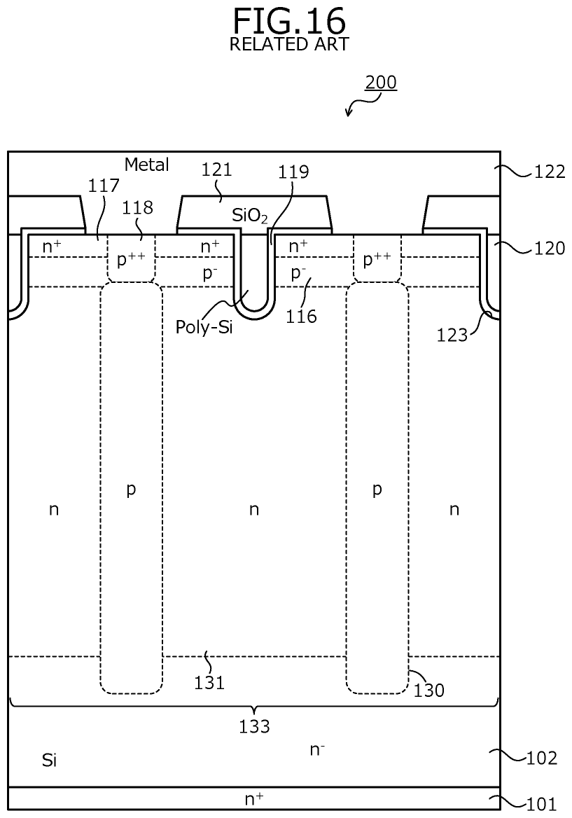

Next, a structure of a semiconductor device according to a fourth embodiment is described. FIG. 15 is a cross-sectional view depicting the structure of the silicon carbide SJ-MOSFET according to the fourth embodiment. As depicted in FIG. 15, a silicon carbide SJ-MOSFET 303 according to the fourth embodiment differs from the silicon carbide SJ-MOSFET 302 according to the third embodiment in that directly beneath the trenches 23, the first p-type column regions 30-1 of the p-type column regions 30 are not provided and between the trenches 23, the first p-type column regions 30-1 of the p-type column regions 30 are provided.

In the fourth embodiment, of the p-type column regions 30, the p-type column regions 30 directly beneath the trenches 23 are formed shallower than the p-type column regions 30 between the trenches 23. As a result, the breakdown voltage directly beneath the trenches 23 is higher, enabling an occurrence of avalanche breakdown at the bottoms of the trenches 23 to be suppressed.

Further, the silicon carbide SJ-MOSFET 303 according to the fourth embodiment may be manufactured by changing the openings in the mask by a photolithographic technique when the first p-type column regions 30-1 are formed, in the method of manufacturing the silicon carbide SJ-MOSFET 302 according to the third embodiment.

In the invention above, while as an example, an instance is described in which a MOS gate structure is formed on the first main surface of the silicon carbide substrate containing silicon carbide, without limitation hereto, various modifications are possible such as changing the type of the wide bandgap semiconductor (for example, to gallium nitride (GaN), etc.), surface orientation of the substrate main surface, etc. Further, in the embodiments of the present invention, while the first conductivity type is assumed to be an n-type and the second conductivity type is assumed to a p-type, the present invention is similarly implemented when the first conductivity type is a p-type and the second conductivity type is an n-type.

According to the invention described above, formation is by SiC, thereby enabling the impurity concentration of the n-type column regions to be increased to be in a range from 1.1×10¹⁶/cm³ 5×10¹⁶/cm³. As a result, high injection carriers when the body diode turns ON may be reduced. Therefore, hard recovery due to hole carriers being pulled out during the reverse recovery state may be suppressed. Furthermore, the impurity concentration of the n-type column regions is high and therefore, the ON resistance decreases.

The superjunction silicon carbide semiconductor device and the method of manufacturing a superjunction silicon carbide semiconductor device achieve an effect in that silicon carbide is used and hard recovery of the body diode may be suppressed.

As described above, the superjunction silicon carbide semiconductor device and the method of manufacturing a superjunction silicon carbide semiconductor device according to the present invention are useful for high-voltage semiconductor devices used in power converting equipment, power source devices of various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A superjunction silicon carbide semiconductor device, comprising:
a silicon carbide semiconductor substrate of a first conductivity type, having at least one surface;
a first semiconductor layer of the first conductivity type, provided over the at least one surface of the silicon carbide semiconductor substrate;
a parallel pn structure in which a plurality of first column regions of the first conductivity type and a plurality of second column regions of a second conductivity type are disposed to repeatedly alternate with one another in a plane parallel to the at least one surface, the parallel pn structure provided in the first semiconductor layer;
a second semiconductor layer of the second conductivity type, provided over the parallel pn structure;
a plurality of first semiconductor regions of the first conductivity type, selectively provided in the second semiconductor layer and having an impurity concentration higher than an impurity concentration of the first semiconductor layer;
a third semiconductor layer of the first conductivity type, provided between the parallel pn structure and the second semiconductor layer, the third semiconductor layer having an impurity concentration higher than the impurity concentration of the plurality of first column regions;
a plurality of trenches penetrating through the plurality of first semiconductor regions and the second semiconductor layer, and reaching the third semiconductor layer;
a plurality of gate electrodes, each provided in a respective one of the trenches via a respective gate insulating film; and
another electrode in contact with the plurality of first semiconductor regions and the second semiconductor layer, wherein
the plurality of first column regions have an impurity concentration that is in a range from 1.1×10¹⁶/cm³ to 5.0×10¹⁶/cm³, and
the plurality of first and second column regions each have crystal defects, the plurality of second column regions having more crystal defects than the plurality of first column regions.

2. The superjunction silicon carbide semiconductor device according to claim 1, further comprising:
a plurality of second semiconductor regions of the second conductivity type, each provided in the third semiconductor layer, in contact with a bottom of one of the trenches; and
a plurality of third semiconductor regions of the second conductivity type, each provided between two of the trenches that are adjacent to each other in the third semiconductor layer.

3. The superjunction silicon carbide semiconductor device according to claim 1, wherein
the impurity concentration of the first semiconductor layer is lower than an impurity concentration of the first column regions, the impurity concentration of the first semiconductor layer being in a range from 1.1×10¹⁶/cm³ to 5.0×10¹⁶/cm³.

4. The superjunction silicon carbide semiconductor device according to claim 1, wherein
the second column regions each have a minority carrier lifetime in a range from 0.5 ns to 500 ns.

5. The superjunction silicon carbide semiconductor device according to claim 1, wherein
the second column regions each have a plurality of periodic structures aligned in a depth direction, each of which has a length in the depth direction in a range from 0.4 μm to 3.0 μm.

6. The superjunction silicon carbide semiconductor device according to claim 1, wherein
the second column regions are provided only in regions between the trenches and not directly beneath the trenches.

7. The superjunction silicon carbide semiconductor device according to claim 1, wherein
the second column regions are provided in first regions between the trenches and in second regions directly beneath the trenches.

8. The superjunction silicon carbide semiconductor device according to claim 7, wherein
the second column regions of the second regions directly beneath the trenches are shallower than the second column regions of the first regions between the trenches so that bottoms of the second column regions in the first regions are closer to the substrate than are bottoms of the second column regions in the second regions.

9. The superjunction silicon carbide semiconductor device according to claim 1, wherein the plurality of second column regions each have an impurity determining a conductivity type thereof, and each have a plurality of periodic structures, each periodic structure having a concentration of the impurity having a periodic distribution in a depth direction.

10. A superjunction silicon carbide semiconductor device, comprising:
a silicon carbide semiconductor substrate of a first conductivity type, having at least one surface;
a first semiconductor layer of the first conductivity type, provided over the at least one surface of the silicon carbide semiconductor substrate;
a parallel pn structure in which a plurality of first column regions of the first conductivity type and a plurality of second column regions of a second conductivity type are disposed to repeatedly alternate with one another in a plane parallel to the at least one surface, the parallel pn structure provided in the first semiconductor layer;
a second semiconductor layer of the second conductivity type, provided over the parallel pn structure;
a plurality of first semiconductor regions of the first conductivity type, selectively provided in the second semiconductor layer and having an impurity concentration higher than an impurity concentration of the first semiconductor layer;
a third semiconductor layer of the first conductivity type, provided between the parallel pn structure and the second semiconductor layer, the third semiconductor layer having an impurity concentration higher than the impurity concentration of the plurality of first column regions;
a plurality of trenches penetrating through the plurality of first semiconductor regions and the second semiconductor layer, and reaching the third semiconductor layer;
a plurality of gate electrodes, each provided in a respective one of the trenches via a respective gate insulating film; and
another electrode in contact with the plurality of first semiconductor regions and the second semiconductor layer, wherein
the plurality of first column regions have an impurity concentration in a range from 1.1×10¹⁶/cm³ to 5.0×10¹⁶/cm³, and
the plurality of second column regions each have an impurity determining a conductivity type thereof, and each have a plurality of periodic structures, each periodic structure having a concentration of the impurity having a periodic distribution in a depth direction.

11. The superjunction silicon carbide semiconductor device according to claim 10, further comprising:
a plurality of second semiconductor regions of the second conductivity type, each provided in the third semiconductor layer, in contact with a bottom of one of the trenches; and
a plurality of third semiconductor regions of the second conductivity type, each provided between two of the trenches that are adjacent to each other in the third semiconductor layer.

12. The superjunction silicon carbide semiconductor device according claim 10, wherein
the impurity concentration of the first semiconductor layer is lower than an impurity concentration of the first column regions, the impurity concentration of the first semiconductor layer being in a range from 1.1×10¹⁶/cm³ to 5.0×10¹⁶/cm³.

13. The superjunction silicon carbide semiconductor device according claim 10, wherein
the second column regions have a minority carrier lifetime in a range from 0.5 ns to 500 ns.

14. The superjunction silicon carbide semiconductor device according claim 10, wherein
the second column regions each have a plurality of periodic structures aligned in a depth direction, each of which has a length in the depth direction in a range from 0.4 μm to 3.0 μm.

15. The superjunction silicon carbide semiconductor device according claim 10, wherein
the second column regions are provided only in regions between the trenches and not directly beneath the trenches.

16. The superjunction silicon carbide semiconductor device according claim 10, wherein
the second column regions are provided in first regions between the trenches and in second regions directly beneath the trenches.

17. The superjunction silicon carbide semiconductor device according to claim 16, wherein
the second column regions of the second regions directly beneath the trenches are shallower than the second column regions of the first regions between the trenches so that bottoms of the second column regions in the first regions are closer to the substrate than are bottoms of the second column regions in the second regions.

18. A method of manufacturing a superjunction silicon carbide semiconductor device, the method comprising:
forming a first semiconductor layer of a first conductivity type, over at least one surface of a silicon carbide semiconductor substrate of the first conductivity type;
forming a parallel pn structure in which a plurality of first column regions of the first conductivity type and a plurality of second column regions of a second conductivity type are disposed to repeatedly alternate with one another in a plane parallel to the at least one surface, the parallel pn structure being provided in the first semiconductor layer;
forming a second semiconductor layer of the second conductivity type over the parallel pn structure;
selectively forming a plurality of first semiconductor regions of the first conductivity type in the second semiconductor layer, the plurality of first semiconductor regions having an impurity concentration higher than an impurity concentration of the first semiconductor layer;
forming a third semiconductor layer of the first conductivity type on the parallel pn structure, between the forming of the parallel pn structure and the forming of the second semiconductor layer, the third semiconductor layer having an impurity concentration higher than an impurity concentration of the plurality of first column regions;
forming a plurality of trenches penetrating through the plurality of first semiconductor regions and the second semiconductor layer, and reaching the third semiconductor layer;
forming each of a plurality of gate electrodes in a respective one of the trenches via a respective gate insulating film; and
forming another electrode in contact with the plurality of first semiconductor regions and the second semiconductor layer, wherein
the plurality of first column regions have an impurity concentration in a range from 1.1×10¹⁶/cm³ to 5.0×10¹⁶/cm³, and
the plurality of second column regions are formed by an ion implantation, and the epitaxial growth and the ion implantation are repeatedly performed, increasing crystal defects of the plurality of second column regions to be greater than crystal defects of the plurality of first column regions.
